(19) United States
(12) Patent Application Publication
(10) Pub. No.: US 2026/0369966 A1
(43) Pub. Date: Nov. 19, 2026

(54) METHOD FOR MANUFACTURING SEMICONDUCTOR APPARATUS

(71) Applicant: Mitsubishi Electric Corporation, Tokyo (JP)

(72) Inventor: Yohei HOKAMA, Tokyo (JP)

(73) Assignee: Mitsubishi Electric Corporation, Tokyo (JP)

(21) Appl. No.: 19/153,806

(22) PCT Filed: May 31, 2023
(86) PCT No.: PCT/JP2023/020350

§ 371 Date: Aug. 5, 2025

(51) Int. Cl. H01S 5/227

(52) U.S. Cl. CPC H01S 5/2275

(57) ABSTRACT

A method for manufacturing a semiconductor apparatus of the present disclosure selectively epitaxially grows first conductivity type layers, non-doped layers, and second conductivity type layers on a surface of a semiconductor substrate to form mesa structures for the individual semiconductor devices. Furthermore, the mesa structures of the plurality of semiconductor devices are simultaneously wet-etched to expose the non-doped layers at inclined portions of the mesa structures. The mesa structures of the plurality of semiconductor devices are simultaneously selectively wet-etched to make widths of the non-doped layers narrower than widths of the second conductivity type layers. The mesa structures of the plurality of semiconductor devices are simultaneously selectively wet-etched to form inverted mesa structures. Furthermore, the inverted mesa structures of the plurality of semiconductor devices are simultaneously dry-etched to form high-mesa structures.

### FIELD

The present disclosure relates to a method for manufacturing a semiconductor apparatus. The present disclosure particularly relates to a method for manufacturing a semiconductor apparatus having a plurality of semiconductor devices each responsible for an optical function in a corresponding one of different wavelength bands.

### BACKGROUND

Wavelength division multiplexing (WDM) communication is known as a technology for achieving large-capacity optical communication.

In a technique disclosed in PTL 1, a first semiconductor laser device having a ridge structure is first formed on a semiconductor substrate. Then, a laminated structure of a second semiconductor laser device is formed that has an oscillation wavelength band different from the oscillation wavelength band of the first semiconductor laser device. Furthermore, the laminated structure is etched to form a ridge structure of the second semiconductor laser device. In this way, a large number of semiconductor laser devices can be formed that have different oscillation wavelength bands from each other, thereby achieving high integration.

### CITATION LIST

### Patent Literature

[PTL 1] JP 2004-207588 A

### SUMMARY

### Technical Problem

In a semiconductor apparatus having a plurality of semiconductor devices each responsible for an optical function in a corresponding one of different wavelength bands, as well as in a multi-wavelength semiconductor laser apparatus, it is desirable that the wavelength characteristics do not vary. It is therefore desirable that the heights of the ridge structures are uniform among the individual semiconductor devices.

In the conventional technique, a semiconductor layer for the second semiconductor laser device is deposited so as to cover the ridge structure of the first semiconductor laser device. Furthermore, the portion where the second semiconductor laser device is to be formed is masked with resist. Then, etching is performed to form a desired ridge structure. This etching also serves to remove the semiconductor layer covering the ridge structure of the first semiconductor laser device to return the structure to its original state. However, the unmasked first semiconductor laser device is also etched, and the height of the ridge structure changes from the time of formation. As a result, the first semiconductor laser device and the second semiconductor laser device have different heights of the ridge structures.

In order to solve the above-described problems, an object of the present disclosure is to provide a method for manufacturing a semiconductor apparatus capable of equalizing heights between ridge structures of a plurality of semiconductor devices each responsible for an optical function in a corresponding one of different wavelength bands.

### Solution to Problem

An aspect of present disclosure is preferably a method for manufacturing a semiconductor apparatus having a plurality of semiconductor devices each responsible for an optical function in a corresponding one of different wavelength bands, the method comprising:
a step of selectively epitaxially growing a first conductivity type layer, a non-doped layer, and a second conductivity type layer on a surface of a semiconductor substrate to form a mesa structure individually for each semiconductor device;
a step of simultaneously wet-etching the mesa structures of the plurality of semiconductor devices to expose the non-doped layer at inclined portions of the mesa structures of the plurality of semiconductor devices;
a step of simultaneously wet-etching the mesa structures of the plurality of semiconductor devices using a chemical liquid to cause each mesa structure to have a width of the non-doped layer narrower than a width of the second conductivity type layer, the chemical liquid having an etching rate for the non-doped layer greater than an etching rate for the first conductivity type layer and the second conductivity type layer;
a step of simultaneously wet-etching the mesa structures of the plurality of semiconductor devices using a chemical liquid to form inverted mesa structures of the plurality of semiconductor devices, the chemical liquid not etching the non-doped layer, the chemical liquid having an etching rate in a depth direction slower than an etching rate in a lateral direction for the first conductivity type layer and the second conductivity type layer;
a step of masking peripheries of the inverted mesa structures of the plurality of semiconductor devices and a surface of the semiconductor substrate;
a step of shaping the mask on the inverted mesa structures of the plurality of semiconductor devices to a predetermined width; and
a step of simultaneously dry-etching regions of the inverted mesa structures of the plurality of semiconductor devices except masked portions until the semiconductor substrate is exposed, to form high-mesa structures of the plurality of semiconductor devices.

### Advantageous Effects of the Invention

According to the aspects of the present disclosure, mesa structures of a plurality of semiconductor devices each responsible for an optical function in a corresponding one of different wavelength bands are selectively epitaxially grown on a semiconductor substrate. Then, the semiconductor layers of the individual semiconductor laser devices are simultaneously wet-etched and dry-etched. This makes it possible to equalize the heights between the ridge structures of a plurality of semiconductor devices.

### BRIEF DESCRIPTION OF DRAWINGS

FIG. 1 is a diagram for describing a method for manufacturing a multi-wavelength semiconductor laser apparatus according to Embodiment 1.

FIG. 2 is a diagram for describing a method for manufacturing a multi-wavelength semiconductor laser apparatus according to Embodiment 1.

FIG. 3 is a diagram for describing a method for manufacturing a multi-wavelength semiconductor laser apparatus according to Embodiment 1.

FIG. 4 is a diagram for describing a method for manufacturing a multi-wavelength semiconductor laser apparatus according to Embodiment 1.

FIG. 5 is a diagram for describing a method for manufacturing a multi-wavelength semiconductor laser apparatus according to Embodiment 1.

FIG. 6 is a diagram for describing a method for manufacturing a multi-wavelength semiconductor laser apparatus according to Embodiment 1.

FIG. 7 is a diagram for describing a method for manufacturing a multi-wavelength semiconductor laser apparatus according to Embodiment 1.

FIG. 8 is a diagram for describing a method for manufacturing a multi-wavelength semiconductor laser apparatus according to Embodiment 1.

FIG. 9 is a diagram for describing a method for manufacturing a multi-wavelength semiconductor laser apparatus according to Embodiment 1.

FIG. 10 is a diagram for describing a method for manufacturing a multi-wavelength semiconductor laser apparatus according to Embodiment 1.

FIG. 11 is a diagram for describing a method for manufacturing a multi-wavelength semiconductor laser apparatus according to Embodiment 1.

FIG. 12 is a diagram for describing a method for manufacturing a multi-wavelength semiconductor laser apparatus according to Embodiment 1.

FIG. 13 is a diagram for describing a method for manufacturing a multi-wavelength semiconductor laser apparatus according to Embodiment 1.

FIG. 14 is a diagram for describing a method for manufacturing a multi-wavelength semiconductor laser apparatus according to Embodiment 1.

FIG. 15 is a diagram for describing a method for manufacturing a multi-wavelength semiconductor laser apparatus according to Embodiment 1.

FIG. 16 is a diagram for describing a method for manufacturing a multi-wavelength semiconductor laser apparatus according to Embodiment 2.

FIG. 17 is a diagram for describing a method for manufacturing a multi-wavelength semiconductor laser apparatus according to Embodiment 2.

FIG. 18 is a diagram for describing a method for manufacturing a multi-wavelength semiconductor laser apparatus according to Embodiment 2.

FIG. 19 is a diagram for describing a method for manufacturing a multi-wavelength semiconductor laser apparatus according to Embodiment 2.

FIG. 20 is a diagram for describing a method for manufacturing a multi-wavelength semiconductor laser apparatus according to Embodiment 2.

FIG. 21 is a diagram for describing a method for manufacturing a multi-wavelength semiconductor laser apparatus according to Embodiment 3.

FIG. 22 is a diagram for describing a method for manufacturing a multi-wavelength semiconductor laser apparatus according to Embodiment 3.

FIG. 23 is a diagram for describing a method for manufacturing a multi-wavelength semiconductor laser apparatus according to Embodiment 3.

FIG. 24 is a diagram for describing a method for manufacturing a multi-wavelength semiconductor laser apparatus according to Embodiment 3.

FIG. 25 is a diagram for describing a method for manufacturing a multi-wavelength semiconductor laser apparatus according to Embodiment 3.

FIG. 26 is a diagram for describing a method for manufacturing a multi-wavelength semiconductor laser apparatus according to Embodiment 3.

FIG. 27 is a diagram for describing a method for manufacturing a multi-wavelength semiconductor laser apparatus according to Embodiment 3.

FIG. 28 is a diagram for describing a method for manufacturing a multi-wavelength semiconductor laser apparatus according to Embodiment 3.

FIG. 29 is a diagram for describing a method for manufacturing a multi-wavelength semiconductor laser apparatus according to Embodiment 3.

FIG. 30 is a diagram for describing a method for manufacturing a multi-wavelength semiconductor laser apparatus according to Embodiment 3.

FIG. 31 is a top view at the positions of the non-doped layers for the semiconductor laser devices according to Embodiment 4.

FIG. 32 is a diagram for describing a method for manufacturing a multi-wavelength semiconductor laser apparatus according to Embodiment 4.

FIG. 33 is a diagram for describing a method for manufacturing a multi-wavelength semiconductor laser apparatus according to Embodiment 4.

FIG. 34 is a diagram for describing a method for manufacturing a multi-wavelength semiconductor laser apparatus according to Embodiment 4.

FIG. 35 is a top view at the positions of the non-doped layers for the semiconductor laser devices according to Embodiment 4.

FIG. 36 is a diagram for describing a method for manufacturing a multi-wavelength semiconductor laser apparatus according to Embodiment 4.

FIG. 37 is a diagram for explaining the arrangement of an insulating film when dry etching is performed on a mesa structure in a comparative example of the present disclosure.

FIG. 38 is a diagram for explaining the case where dry etching is performed on the mesa structure shown in FIG. 37 in a comparative example of the present disclosure.

FIG. 39 is a diagram for explaining the process of forming the second semiconductor laser device in the prior art.

FIG. 40 is a diagram for explaining the case where etching is performed to the intended depth on the structure shown in FIG. 39 in the prior art.

FIG. 41 is a diagram for explaining the case where excessive etching is performed on the structure shown in FIG. 39 in the prior art.

### DESCRIPTION OF EMBODIMENTS

A method for manufacturing a semiconductor apparatus according to an embodiment of the present disclosure will be described with reference to the drawings. The same or corresponding components are given the same reference numerals, and repeated description may be omitted.

### Embodiment 1

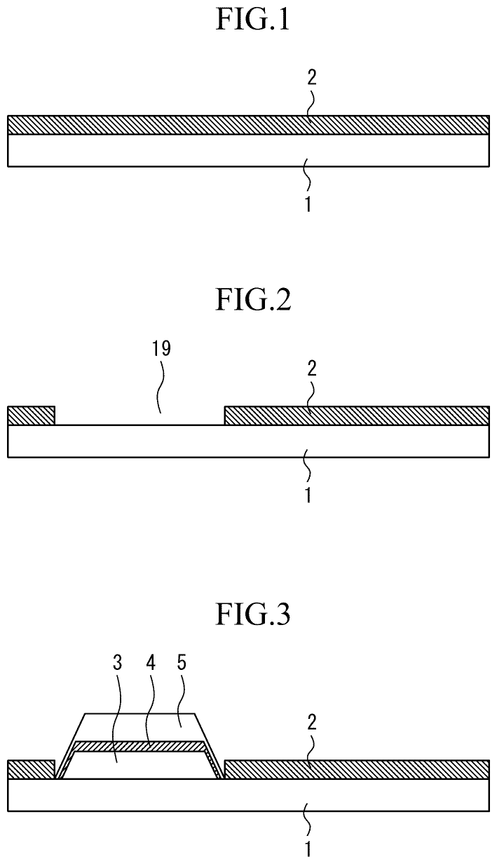

FIGS. 1 to 15 are diagrams for describing a method for manufacturing a multi-wavelength semiconductor laser apparatus 100 according to Embodiment 1. First, as shown in FIG. 1, an insulating film 2 is deposited on a semiconductor substrate 1. Examples of the material for the insulating film 2 include SiO₂ and SiN, but any type of material is possible as long as it can be epitaxially grown, which will be described later.

Next, as shown in FIG. 2, an opening 19 is formed in a region of the insulating film 2 in which a first semiconductor laser device 110 is to be formed, and the semiconductor substrate 1 is exposed. Methods for processing the insulating film 2 may be dry etching such as reactive ion etching (RIE) or inductively coupled plasma (ICP) etching.

Thereafter, as shown in FIG. 3, a first conductivity type layer 3, a non-doped layer 4, and a second conductivity type layer 5 of the first semiconductor laser device 110 are selectively epitaxially grown in the opening 19 to form a mesa structure. The first conductivity type layer 3 and the second conductivity type layer 5 are conductivity type layers such as InP layers doped to p-type or n-type. The non-doped layer 4 is an active layer made of a ternary or quaternary compound semiconductor such as InGaAsP, AlGaInAs, or InGaAs. This point is not limited to the first semiconductor laser device 110, but is also common to semiconductor laser devices that are responsible for oscillation in other wavelength bands.

Next, the insulating film 2 is removed. Methods for removing the insulating film 2 include wet etching with buffered hydrofluoric acid (BHF) or hydrofluoric acid (HF).

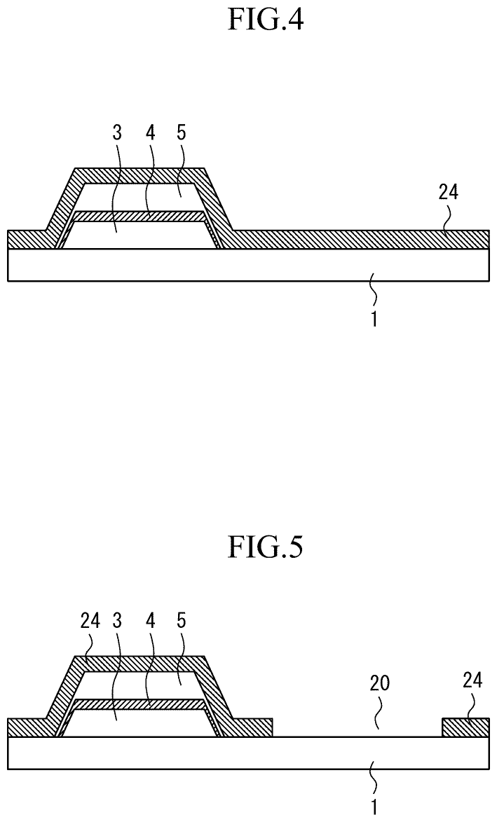

Furthermore, as shown in FIG. 4, the insulating film 24 is re-deposited.

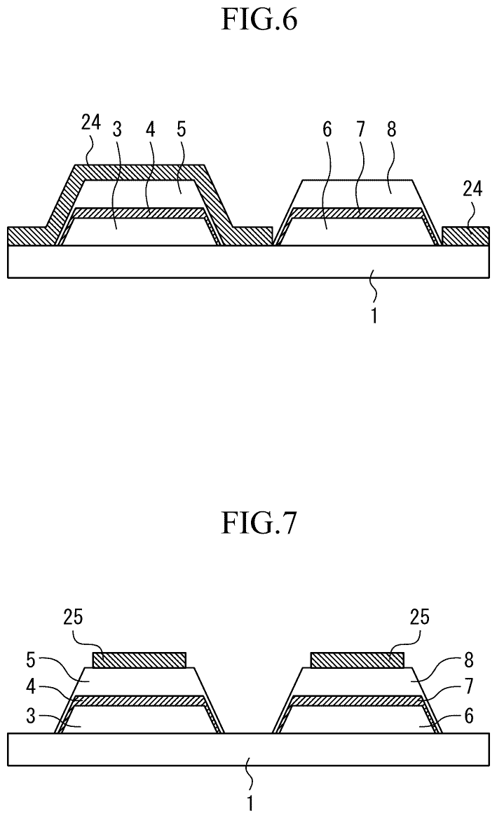

After that, as shown in FIG. 5, an opening 20 is formed in the region of the insulating film 24 in which a second semiconductor laser device 120 is to be formed, and the semiconductor substrate 1 is exposed. Thereafter, as shown in FIG. 6, a first conductivity type layer 6, a non-doped layer 7, and a second conductivity type layer 8 of the second semiconductor laser device 120 are selectively epitaxially grown in the opening 20 to form a mesa structure.

For simplicity of description, only the mesa structures for the first semiconductor laser device 110 and the second semiconductor laser device 120 are shown in the following. However, if necessary, the mesa structures for the third and fourth semiconductor laser devices may be selectively epitaxially grown in a similar manner. This allows the formation of a plurality of semiconductor layers for the semiconductor laser devices each responsible for oscillation in a corresponding one of individual wavelength bands. Here, the mesa structure is a layer including a first conductivity type layer, a non-doped layer, and a second conductivity type layer.

Next, after the insulating film 24 is removed, an insulating film 25 is deposited. Furthermore, as shown in FIG. 7, the insulating film 25 is removed except on the second conductivity type layers 5 and 8.

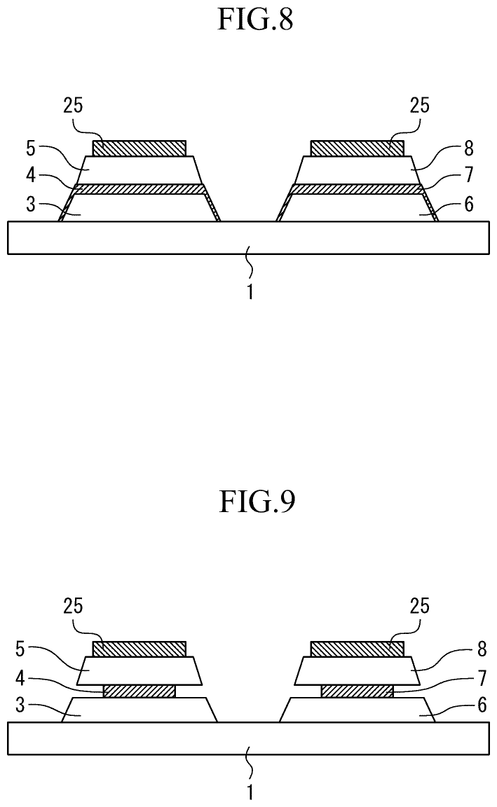

Next, as shown in FIG. 8, the mesa structures that have been selectively epitaxially grown are wet-etched to expose the non-doped layers 4, 7 at inclined portions of the mesa structures. In wet etching, a chemical liquid is desirable that is capable of isotropic etching for all of the first conductivity type layers 3, 6, the non-doped layers 4, 7, and the second conductivity type layers 5, 8. Examples of the chemical liquid include sulfuric acid.

Then, as shown in FIG. 9, the non-doped layers 4, 7 are selectively wet-etched from the inclined portions of the mesa structures. In the wet etching, a chemical liquid is used that has an etching rate for the non-doped layers 4, 7 greater than an etching rate for the first conductivity type layers 3, 6 and the second conductivity type layers 5, 8. In the case of the non-doped layers 4, 7 made of ternary or quaternary compound semiconductors as disclosed herein, examples of the suitable chemical liquid include tartaric acid. As a guideline for the amount of wet etching, it is desirable to etch until the width of the non-doped layers 4, 7 becomes narrower than the width of the second conductivity type layers 5, 8.

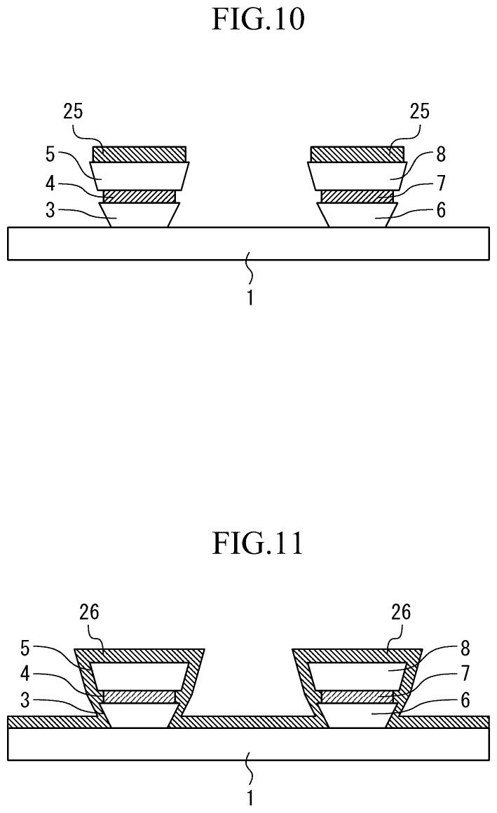

Next, as shown in FIG. 10, the first conductivity type layers 3, 6 and the second conductivity type layers 5, 8 are selectively wet-etched. The chemical liquid to be used must not etch the non-doped layers 4, 7. In addition, for the first conductivity type layers 3, 6 and the second conductivity type layers 5, 8, the etching rate in the depth direction must be relatively slower than the etching rate in the lateral direction. As disclosed herein, for the first conductivity type layers 3, 6 and the second conductivity type layers 5, 8, which are made of InP layers doped to p-type or n-type, hydrogen bromide (HBr) is an example of a suitable chemical liquid. Wet-etching with an anisotropic chemical liquid makes it possible simultaneously to form inverted mesa semiconductor layers in each semiconductor laser devices. Here, the inverted mesa structure refers to a structure in which the width decreases from the mask of the insulating film 25 toward the semiconductor substrate 1.

Next, as shown in FIG. 11, an insulating film 26 is deposited around the ridge portions of the inverted mesa structures and on the surface of the semiconductor substrate 1.

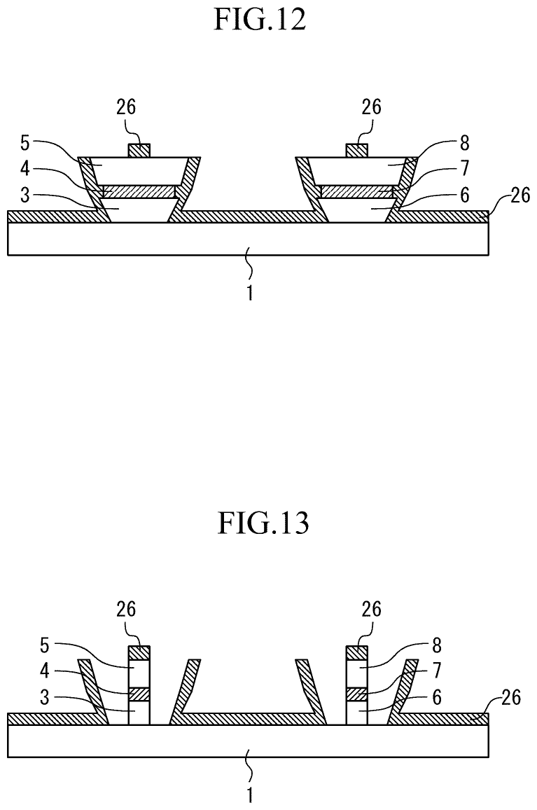

Furthermore, as shown in FIG. 12, both ends of the insulating film 26 are removed on the ridge of each inverted mesa structure to shape the insulating film 26 with a predetermined width. The predetermined width refers to the width of a high-mesa structure to be described later. Here, as shown in FIG. 12, the insulating film 26 deposited on the inclined portions of the inverted mesa structures and the insulating film 26 on the surface of the semiconductor substrate 1 are left.

Then, as shown in FIG. 13, the first conductivity type layers 3, 6, the non-doped layers 4, 7, and the second conductivity type layers 5, 8 are dry-etched to expose the semiconductor substrate 1. In dry etching, each insulating film 26 serves as a mask. For the semiconductor layers on the inclined portions of inverted mesa structures, the dry etching first reaches the second conductivity type layers 5, 8, then the non-doped layers 4, 7 and the first conductivity type layers 3, 6 in sequence, and finally reaches the insulating film 26 on the inclined portions. After reaching the insulating film 26 on the inclined portions, dry etching does not proceed.

On the other hand, for the semiconductor layers on the semiconductor substrate 1, the dry etching first reaches the second conductivity type layers 5, 8, then the non-doped layers 4, 7 and the first conductivity type layers 3, 6 in sequence, and finally reaches the semiconductor substrate 1. Terminating the dry etching when the dry etching reaches the semiconductor substrate 1 makes it possible to form the high-mesa structures shown in FIG. 13.

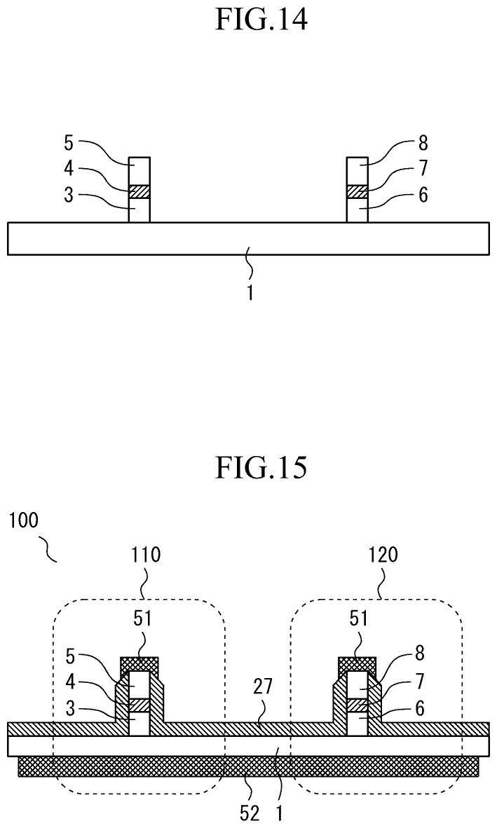

After that, all of the insulating films 26 are removed as shown in FIG. 14. Furthermore, as shown in FIG. 15, an insulating film 27 is deposited on the sidewalls of the high-mesa structures and on the semiconductor substrate 1. Furthermore, upper surface electrodes 51 are each formed on the upper part of a high-mesa structure, and a back surface electrode 52 is formed on the back surface of the semiconductor substrate 1. As a result, it is possible to produce a multi-wavelength semiconductor laser apparatus 100 including a first semiconductor laser device 110 and a second semiconductor laser device 120.

As described above, in the present disclosure, the mesa structure of each semiconductor laser device is selectively epitaxially grown on the semiconductor substrate 1. Then, the mesa structures of the individual semiconductor laser devices are simultaneously wet-etched and dry-etched. In this case, the processing variation in etching is uniform for the mesa structures of the individual semiconductor laser devices. This makes it possible to equalize the heights between the ridge structures in the semiconductor laser devices each responsible for oscillation in a corresponding one of wavelength bands.

### Modification of Embodiment 1

The non-doped layers 4, 7 are not limited to active layers for semiconductor lasers, but may be light absorption layers for semiconductor modulators or core layers for semiconductor optical amplifiers. This makes it possible to produce semiconductor modulators or semiconductor optical amplifiers for multi-wavelength operation. Note that this point is common to all of the following embodiments.

### Embodiment 2

This embodiment shows a method for manufacturing an embedded ridge type multi-wavelength semiconductor laser apparatus 200. Note that the description of FIGS. 1 to 13 of Embodiment 1 is also common to this embodiment, and the description thereof will be omitted here.

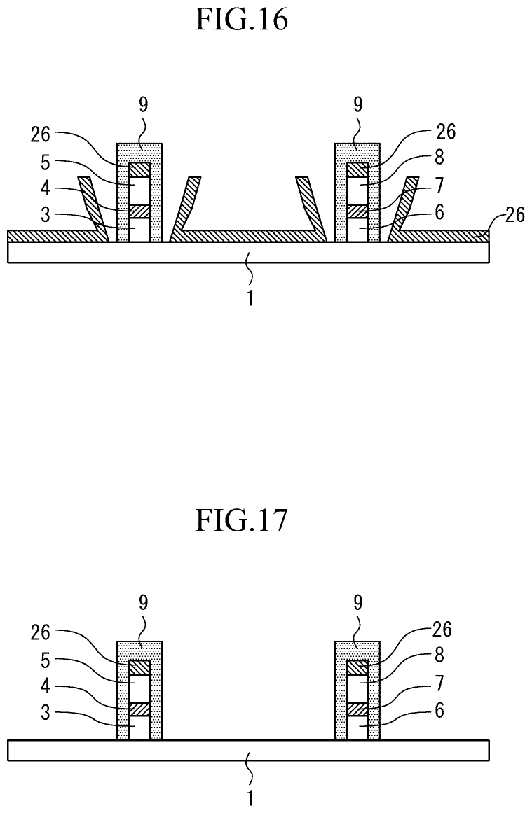

Next, as shown in FIG. 16, the ridge portion of each high-mesa structure is covered with resist 9. Furthermore, mask transfer exposure and development processing are performed.

Next, as shown in FIG. 17, wet etching is performed to remove the insulating film 26 except the insulating film 26 on the upper part of each high-mesa structure covered with the resist 9.

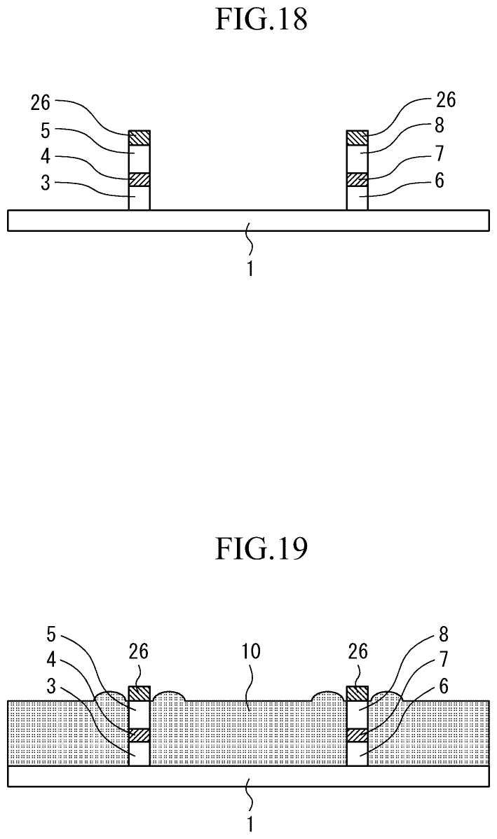

Then, as shown in FIG. 18, the resists 9 are removed. Furthermore, as shown in FIG. 19, the current blocking layer 10 is epitaxially grown so as to fill between high-mesa structures. Note that any type of material may be used for the current blocking layer 10 as long as it has high resistance to the current flowing through the non-doped layers.

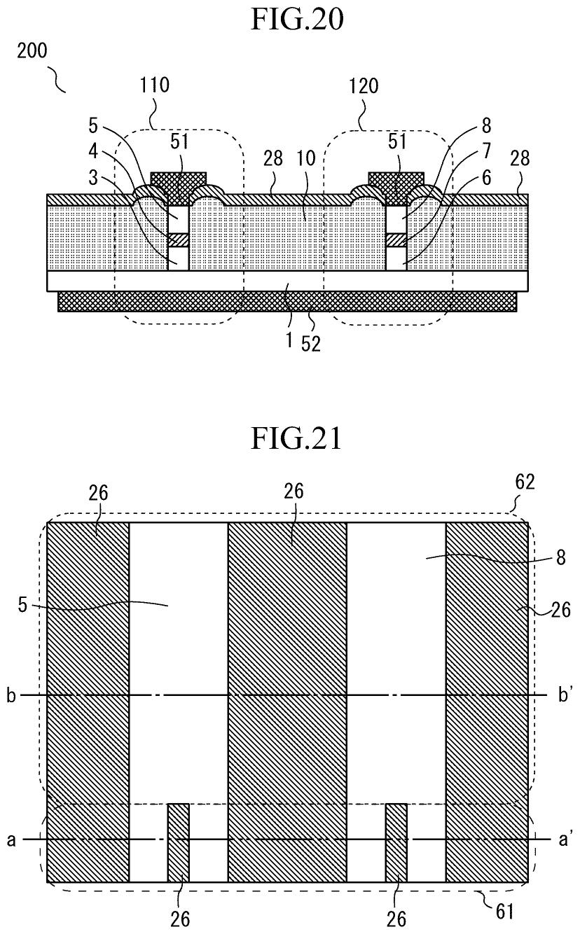

Furthermore, the insulating film 26 on the upper part of the ridge of each high-mesa structure is removed. Furthermore, as shown in FIG. 20, an insulating film 28 is deposited on the upper part of the current blocking layer 10. Furthermore, an upper surface electrode 51 is formed on the upper part of the ridge of each high-mesa structure, and a back surface electrode 52 is formed on the back surface of the semiconductor substrate 1. As a result, it is possible to produce an embedded ridge type multi-wavelength semiconductor laser apparatus 200 in which the ridge portions of the high-mesa structures are embedded in the current blocking layer 10. The current blocking layer 10 restricts the amount of current flowing between the upper surface electrodes 51 and the back surface electrode 52. This makes it possible to reduce heat generation during laser operation. In terms of stable operation, the multi-wavelength semiconductor laser apparatus 200 of this embodiment exhibits a more advantageous effect than the multi-wavelength semiconductor laser apparatus 100 of Embodiment 1.

### Embodiment 3

This embodiment shows a method for manufacturing a multiplexer built-in multi-wavelength semiconductor laser apparatus 300. The description of FIGS. 1 to 11 of Embodiment 1 is also common to this embodiment, and the description thereof will be omitted here.

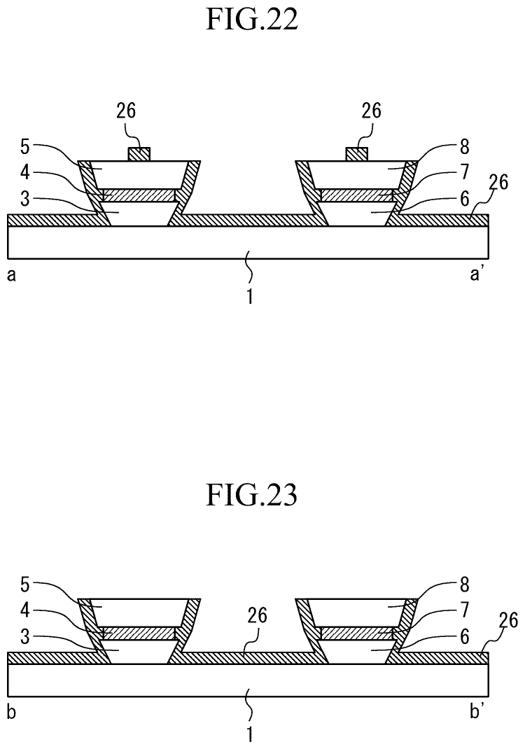

Next, as in FIG. 12, the insulating films 26 with a predetermined width are each shaped on the ridge of the inverted mesa structure. However, as shown in FIG. 21, in a first region 61 where the inverted mesa structures extend, the insulating films 26 on the inverted mesa structures are each shaped to a predetermined width, and in a second region 62 where the inverted mesa structures extend, the insulating films 26 on the inverted mesa structures are removed. Here, FIG. 21 is a top view of the semiconductor substrate 1. It should be noted that the resonator length direction of each semiconductor laser device is the up-down direction on the paper. The second region 62 is positioned to be adjacent to the first region 61 in the resonator length direction. FIG. 22 is an a-a′ cross-sectional view of the first region 61 in FIG. 21. Likewise, FIG. 23 is a b-b′ cross-sectional view of the second region 62.

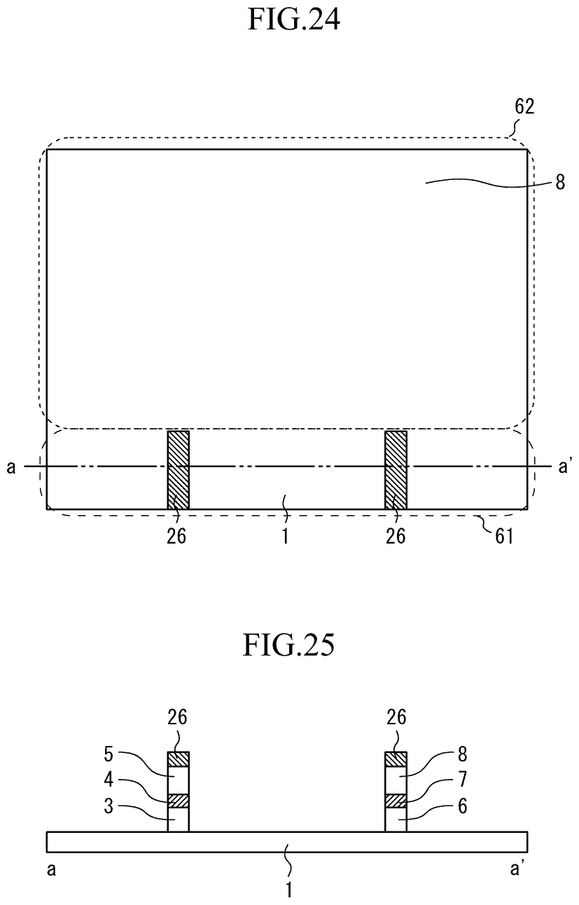

Next, as in FIG. 13, dry etching is performed until the semiconductor substrate 1 is exposed in the region of each inverted mesa structure except the masked portion. Next, the similar steps as those in FIGS. 16 to 18 of Embodiment 2 are performed. This leaves only the ridge portions of the high-mesa structures and the insulating films 26 on the upper parts thereof and exposes the semiconductor substrate 1, in the first region 61 as shown in FIG. 24. In contrast, in the second region 62, the semiconductor substrate 1 is exposed over the entire area. FIG. 25 is an a-a′ cross-sectional view of the first region 61 in FIG. 24.

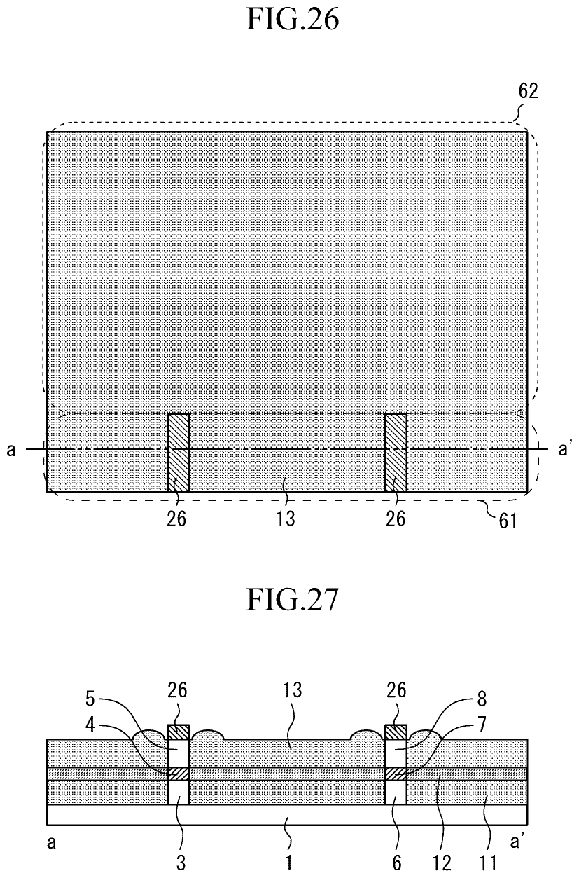

Then, as shown in FIGS. 26 and 27, a waveguide layer including a waveguide core layer 12, a waveguide first clad layer 11, and a waveguide second clad layer 13 is laminated between the high-mesa structures. As shown in FIG. 26, the waveguide layer is laminated not only in the first region 61 but also in the second region 62 where no high-mesa structure is present. Furthermore, FIG. 27 is an a-a′ cross-sectional view of the first region 61 in FIG. 26. As shown in FIG. 27, the waveguide core layer 12 is formed to connect the non-doped layer 4 and the non-doped layer 7. The waveguide first clad layer 11 is formed to connect the first conductivity type layer 3 and the first conductivity type layer 6. The waveguide second clad layer 13 is formed to connect the second conductivity type layer 5 and the second conductivity type layer 8.

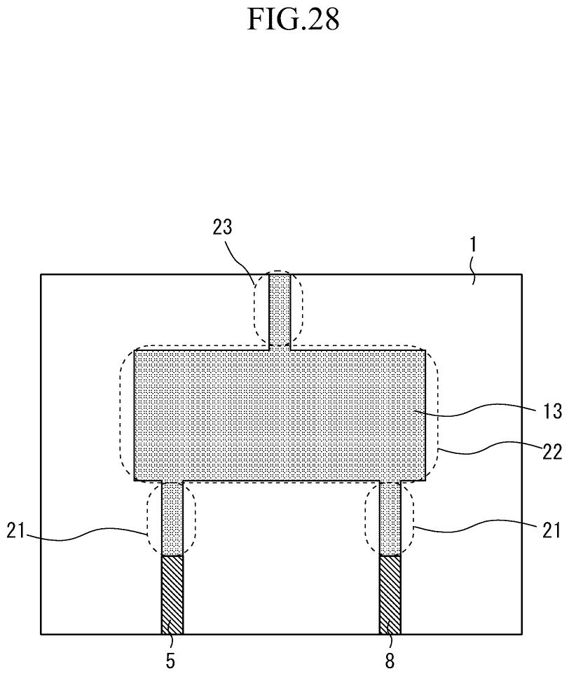

Then, the insulating films 26 in the first region 61 are removed. Furthermore, as shown in FIG. 28, the waveguide core layer 12, the waveguide first clad layer 11, and the waveguide second clad layer 13 are processed to create a waveguide. The waveguide includes input sections 21, a multiplexer 22, and an output section 23. As a result, it comes to be possible to multiplex the light oscillated from the individual semiconductor laser devices using the multiplexer 22 and to emit the multiplexed light from the output section 23.

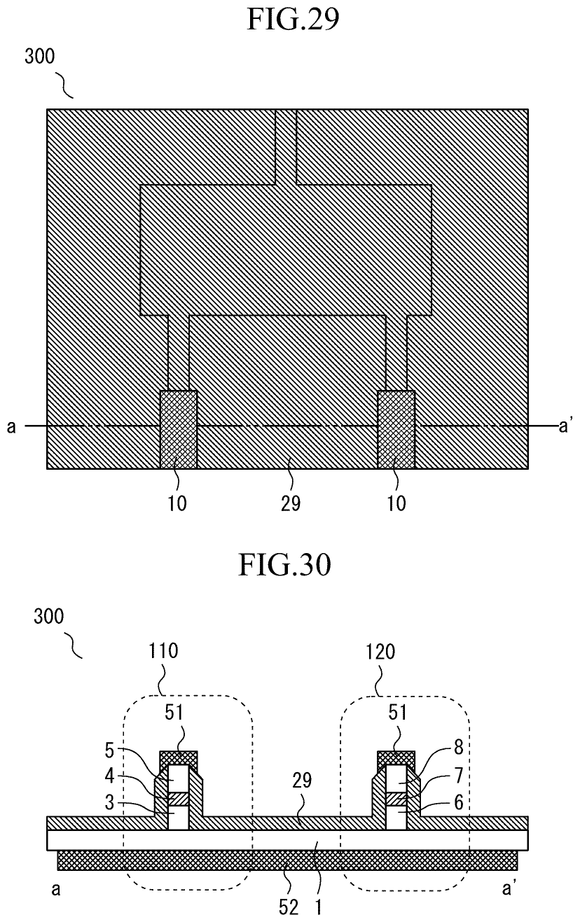

Furthermore, as shown in FIG. 29, an insulating film 29 is deposited on the sidewalls of the high-mesa structures, the semiconductor substrate 1, and the waveguide. Furthermore, an upper surface electrode 51 is formed on the upper part of the ridge of each high-mesa structure, and a back surface electrode 52 is formed on the back surface of the semiconductor substrate 1. This makes it possible to produce the multiplexer built-in multi-wavelength semiconductor laser apparatus 300. FIG. 30 is an a-a′ cross-sectional view in FIG. 29.

Here, in order to minimize the optical waveguide loss from the individual semiconductor laser devices to the multiplexer 22, it is desirable that the waveguide core layer 12 have a thickness and a height from the semiconductor substrate 1 that are equal to those of the non-doped layers 4, 7. As described above, the present disclosure makes it possible to equalize the heights between the ridge structures for the individual semiconductor laser devices. Furthermore, the heights between the non-doped layers 4, 7 can also be equalized. Accordingly, in the present disclosure, it is possible to match the height of the waveguide core layer 12 to the heights of the non-doped layers 4, 7 of the individual semiconductor laser devices. As a result, the loss due to optical guide mode mismatch occurring at the boundaries between the non-doped layers 4, 7 and the input sections 21 can be made uniform for the individual semiconductor laser devices.

### Modification of Embodiment 3

The multiplexer built-in multi-wavelength semiconductor laser apparatus 300 described in this embodiment can be modified to the embedded ridge type described in Embodiment 2. In this modification, after the high-mesa structures of FIG. 25 are formed, a current blocking layer 10 is epitaxially grown in the first region 61 to fill between the high-mesa structures. In contrast, in the second region 62, as shown in FIG. 26, a waveguide layer is laminated that includes a waveguide core layer 12, a waveguide first clad layer 11, and a waveguide second clad layer 13. Furthermore, as shown in FIG. 28, the waveguide layer is processed to create a waveguide. As a result, the multi-wavelength semiconductor laser apparatus 300 has a structure in which each high-mesa structure is embedded in the current blocking layer 10. In this case, the effect of combining Embodiment 2 and Embodiment 3 can be obtained.

### Embodiment 4

This embodiment illustrates a method for manufacturing a multi-wavelength semiconductor laser apparatus 400 incorporating a modulator or an optical amplifier. The multi-wavelength semiconductor laser apparatus 400 has a configuration in which the multi-wavelength semiconductor laser apparatus 300 described in Embodiment 3 further includes a modulator or an optical amplifier. In the following description, the manufacturing method will be explained in the case where the multi-wavelength semiconductor laser apparatus 400 includes a modulator. As for the optical amplifier, it should be interpreted as replacing the modulator with the optical amplifier in the subsequent description.

First, during the steps shown in FIGS. 1 through 6 for selectively epitaxially growing the semiconductor layers of the individual semiconductor laser devices, a mesa structure for a modulator is selectively epitaxially grown between the mesa structures of the individual semiconductor laser devices. The mesa structure for the modulator includes a non-doped layer for the modulator, a first conductivity type layer for the modulator, and a second conductivity type layer for the modulator.

FIG. 31 is a top view at the positions of the non-doped layers 4 and 7 for the semiconductor laser devices according to Embodiment 4. A non-doped layer 14 for a first modulator is formed between the non-doped layer 4 for the first semiconductor laser device 110 and the non-doped layer 7 for the second semiconductor laser device 120. The first modulator operates as a modulator for the oscillation wavelength of the first semiconductor laser device 110.

Similarly, a non-doped layer 15 for a second modulator is formed between the non-doped layer 7 for the second semiconductor laser device 120 and a non-doped layer of a third semiconductor laser device (not shown). The second modulator operates as a modulator for the oscillation wavelength of the second semiconductor laser device 120. In this way, each modulator functions for the oscillation wavelength of an adjacent semiconductor laser device, which is not shared with any other modulator.

The non-doped layer 14 for the first modulator and non-doped layer 15 for the second modulator are selectively epitaxially grown to have a height equal to that of the non-doped layers 4 and 7 of the semiconductor laser devices. This enables the light oscillated from the non-doped layers 4 and 7 of the semiconductor laser devices to be modulated by the modulators.

The mesa structure of the semiconductor laser device includes, on the semiconductor substrate 1, a first extension portion 41 and a second extension portion 42 extending in the resonator length direction from the respective ends of the laser resonator. Furthermore, a crank portion 43, connecting the first extension portion 41 and the second extension portion 42 with two obtuse angles alternately connected, is provided. Each mesa structure for the modulators also has the same shape. The first extension portion 41 of the first semiconductor laser device 110 and the second extension portion 42 of the first modulator are formed on the same straight line. Similarly, the first extension portion 41 of the second semiconductor laser device 120 and the second extension portion 42 of the second modulator are formed on the same straight line.

Note that the pattern of the non-doped layers 4 and 7 for the semiconductor laser devices, and the non-doped layer 14 for the first modulator and the non-doped layer 15 for the second modulator, shown in FIG. 31, is merely one example and is not limited thereto.

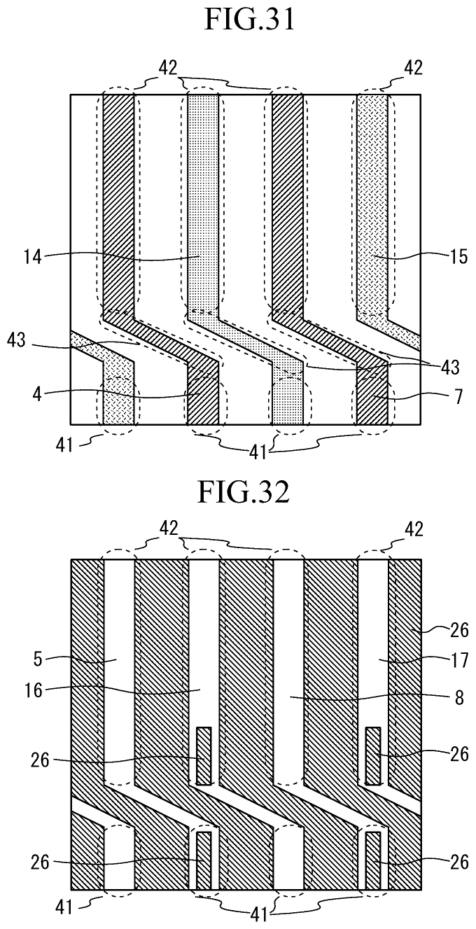

Next, the same steps as in FIGS. 7 through 11 are performed. As a result, the mesa structures of the semiconductor laser devices and those of the modulators become inverted mesa structures. Furthermore, as in FIG. 12, an insulating film 26 is formed on the ridges of the inverted mesa structures. However, in this embodiment, as shown in FIG. 32, the insulating film 26 is formed on the first extension portion 41 of each semiconductor laser device and the second extension portion 42 of the corresponding modulator. Note that the insulating film 26 formed on the second extension portion 42 of the modulator is not formed over the entire extending direction, but only on the side facing the first extension portion 41.

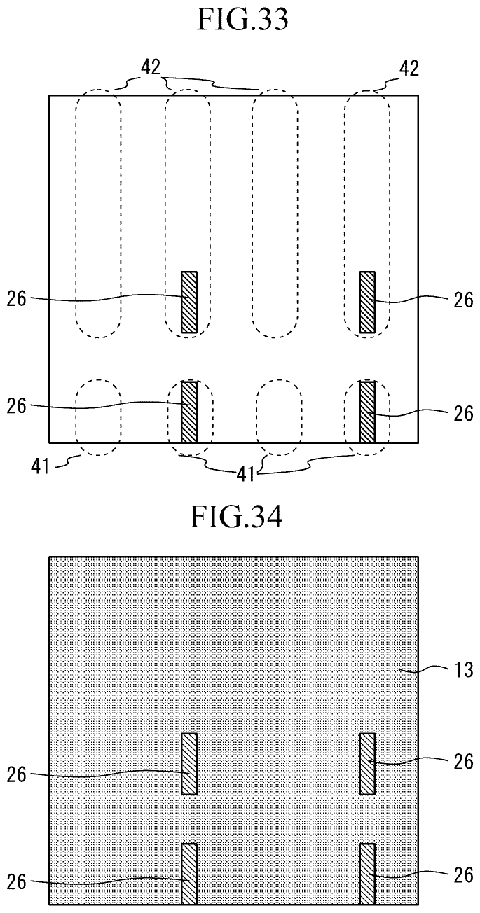

Then, as in FIG. 13, dry etching is performed until the semiconductor substrate 1 is exposed in regions other than the masked portions of the inverted mesa structures. Next, the same steps as in FIGS. 16 through 18 of Embodiment 2 are performed. As a result, as shown in FIG. 33, only the ridge portions of the high-mesa structures and the insulating films 26 on their upper parts are left at the first extension portions 41 of the semiconductor laser devices and the second extension portions 42 of the modulators, and the semiconductor substrate 1 is exposed.

Thereafter, as in FIG. 26 of Embodiment 3, a waveguide layer including a waveguide core layer 12, a waveguide first clad layer 11, and a waveguide second clad layer 13 is laminated between the high-mesa structures and on the exposed surface of the semiconductor substrate 1. This results in the state shown in FIG. 34.

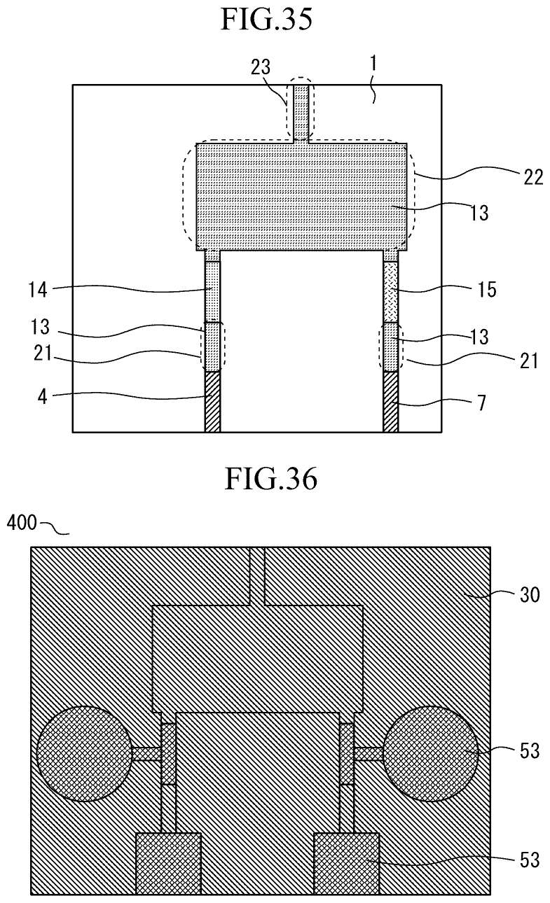

Next, as in FIG. 28, the waveguide layer is processed to form a waveguide. This results in the state shown in FIG. 35. FIG. 35 is a top view at the positions of the non-doped layers 4 and 7 for the semiconductor laser devices.

Finally, as shown in FIG. 36, an insulating film 30 is formed on the sidewalls of the high-mesa structures for each semiconductor laser device and modulator, on the semiconductor substrate 1, and on the waveguide excluding the modulator. Furthermore, an upper surface electrode 53 is disposed covering the upper portion of each high-mesa structure of the semiconductor laser devices and modulators. As a result, a multi-wavelength semiconductor laser apparatus 400 incorporating a modulator can be manufactured.

### Modification of Embodiment 4

Similarly to the modification of Embodiment 3, the multi-wavelength semiconductor laser apparatus 400 can also be modified into an embedded ridge type. This configuration provides the combined effects of Embodiment 2 and Embodiment 4.

As described above, according to the present disclosure, it is possible to provide a method for manufacturing a semiconductor apparatus that can equalize the heights of the ridge structures in the semiconductor devices each responsible for an optical function in a corresponding one of different wavelength bands.

The present disclosure is not limited to the above-described embodiments, and various modifications may be made without departing from the scope of the present disclosure. The respective embodiments may also be appropriately combined, in which case the combined effects can be obtained.

### Comparative Example 1

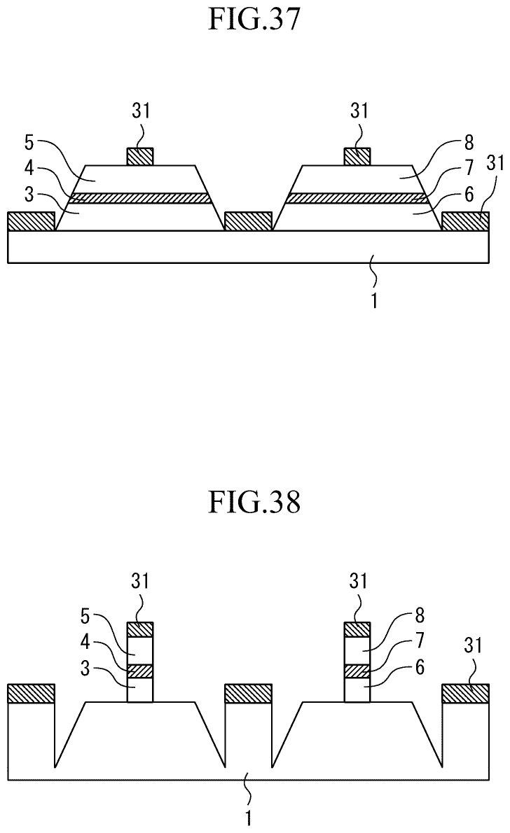

In the present disclosure, it was described that the desired high-mesa structure shown in FIG. 14 can be obtained by performing dry etching on the inverted mesa structure. It should be noted that the desired high-mesa structure cannot be formed by performing dry etching on the mesa structure. FIG. 37 is a diagram for explaining the arrangement of an insulating film 31 when dry etching is performed on a mesa structure in a comparative example of the present disclosure. To obtain the structure shown in FIG. 37, the insulating film 2 is removed from the state of FIG. 6, and then a new insulating film 31 is deposited. Further, both ends of the insulating film 31 on the ridge of the mesa structure are removed to leave only the width corresponding to the high-mesa structure. In addition, the insulating film 31 on the inclined portion of the mesa structure is also removed.

FIG. 38 is a diagram for explaining the case where dry etching is performed on the mesa structure shown in FIG. 37 in a comparative example of the present disclosure. By its nature, dry etching proceeds vertically at an equal depth in all regions except for the areas masked by the insulating film 31. As a result, the shape of the inclined portion of the mesa structure is directly reproduced on the semiconductor substrate 1. For this reason, regardless of the arrangement of the insulating film 31 shown in FIG. 37, so long as dry etching is applied to the semiconductor layer of the mesa structure, the desired high-mesa structure cannot be obtained, or additional processing is required after dry etching.

### Comparative Example 2

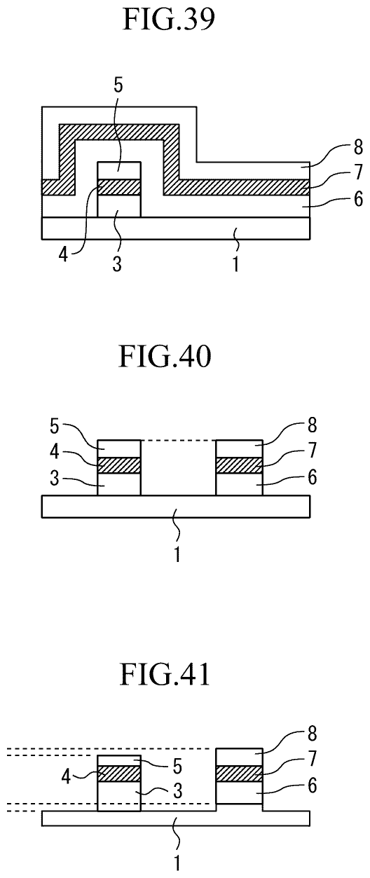

In the prior art, it was described that the ridge structures of the first semiconductor laser device 110 and the second semiconductor laser device 120 have different heights. Here, a more detailed explanation is given with reference to the drawings. The reference numerals are the same as those in the present disclosure. FIG. 39 is a diagram for explaining the process of forming the second semiconductor laser device 120 in the prior art. A semiconductor layer for the second semiconductor laser device 120 is deposited so as to cover the ridge structure of the first semiconductor laser device 110.

FIG. 40 is a diagram for explaining the case where etching is performed to the intended depth on the structure shown in FIG. 39 in the prior art. The area of the semiconductor layer for the second semiconductor laser device 120 that covers the ridge structure of the first semiconductor laser device 110 is removed by etching. If etching is performed to the exact intended depth, the first semiconductor laser device 110 can be restored to its original ridge structure.

FIG. 41 is a diagram for explaining the case where excessive etching is performed on the structure shown in FIG. 39 in the prior art. The second conductivity type layer 5 of the first semiconductor laser device 110 and the semiconductor substrate 1 are also etched. In this way, in the first semiconductor laser device 110 that is not masked by resist or the like, the thickness of the second conductivity type layer 5 is altered. On the other hand, the second semiconductor laser device 120 is masked by resist, so its second conductivity type layer 8 is not etched even when etching is excessive. As a result, the ridge structures of the first semiconductor laser device 110 and the second semiconductor laser device 120 have different heights.

### REFERENCE SIGNS LIST

1: semiconductor substrate, 2: insulating film, 3: first conductivity type layer, 4: non-doped layer, 5: second conductivity type layer, 6: first conductivity type layer, 7: non-doped layer, 8: second conductivity type layer, 9: resist, 10: current blocking layer, 11: waveguide first clad layer, 12: waveguide core layer, 13: waveguide second clad layer, 14: first non-doped layer for modulator, 15: second non-doped layer for modulator, 16: first conductivity type layer for modulator, 17: second conductivity type layer for modulator, 19, 20: openings, 21: input section, 22: multiplexer, 23: output section, 24-31: insulating films, 41: first extension portion, 42: second extension portion, 43: crank portion, 51, 53: upper surface electrodes, 52: back surface electrode, 61: first region, 62: second region, 100, 200, 300, 400: multi-wavelength semiconductor laser apparatuses, 110: first semiconductor laser device, 120: second semiconductor laser device.

1. A method for manufacturing a semiconductor apparatus having a plurality of semiconductor devices each responsible for an optical function in a corresponding one of different wavelength bands, the method comprising:
a step of selectively epitaxially growing a first conductivity type layer, a non-doped layer, and a second conductivity type layer on a surface of a semiconductor substrate to form a mesa structure individually for each semiconductor device;
a step of simultaneously wet-etching the mesa structures of the plurality of semiconductor devices to expose the non-doped layer at inclined portions of the mesa structures of the plurality of semiconductor devices;
a step of simultaneously wet-etching the mesa structures of the plurality of semiconductor devices using a chemical liquid to cause each mesa structure to have a width of the non-doped layer narrower than a width of the second conductivity type layer, the chemical liquid having an etching rate for the non-doped layer greater than an etching rate for the first conductivity type layer and the second conductivity type layer;
a step of simultaneously wet-etching the mesa structures of the plurality of semiconductor devices using a chemical liquid to form inverted mesa structures of the plurality of semiconductor devices, the chemical liquid not etching the non-doped layer, the chemical liquid having an etching rate in a depth direction slower than an etching rate in a lateral direction for the first conductivity type layer and the second conductivity type layer;
a step of masking peripheries of the inverted mesa structures of the plurality of semiconductor devices and a surface of the semiconductor substrate;
a step of shaping the mask on the inverted mesa structures of the plurality of semiconductor devices to a predetermined width; and
a step of simultaneously dry-etching regions of the inverted mesa structures of the plurality of semiconductor devices except masked portions until the semiconductor substrate is exposed, to form high-mesa structures of the plurality of semiconductor devices.

2. The method for manufacturing a semiconductor apparatus according to claim 1, comprising a step of embedding each of the high-mesa structures in a current blocking layer having a high resistance to a current flowing through the non-doped layer.

3. The method for manufacturing a semiconductor apparatus according to claim 1, wherein the high-mesa structures are each a high-mesa structure for a laser, for a modulator, or for an optical amplifier.

4. The method for manufacturing a semiconductor apparatus according to claim 1, further comprising:
a step of laminating a waveguide core layer and a waveguide clad layer on the semiconductor substrate-1, the waveguide core layer and the waveguide clad layer connecting the high-mesa structures of the plurality of semiconductor devices; and
a step of processing the waveguide core layer and the waveguide clad layer to form a waveguide including a multiplexer connected to each of the high-mesa structures of the plurality of semiconductor devices.

5. The method for manufacturing a semiconductor apparatus according to claim 1, wherein the high-mesa structures include a high-mesa structure for a modulator or an optical amplifier, and a high-mesa structure for a laser, and the high-mesa structure for the modulator or optical amplifier, and the high-mesa structure for the laser are linearly connected by a waveguide.

6. The method for manufacturing a semiconductor apparatus according to claim 2, wherein the high-mesa structures are each a high-mesa structure for a laser, for a modulator, or for an optical amplifier.

7. The method for manufacturing a semiconductor apparatus according to claim 2, further comprising:
a step of laminating a waveguide core layer and a waveguide clad layer on the semiconductor substrate 1, the waveguide core layer and the waveguide clad layer connecting the high-mesa structures of the plurality of semiconductor devices; and
a step of processing the waveguide core layer and the waveguide clad layer to form a waveguide including a multiplexer connected to each of the high-mesa structures of the plurality of semiconductor devices.

8. The method for manufacturing a semiconductor apparatus according to claim 3, further comprising:
a step of laminating a waveguide core layer and a waveguide clad layer on the semiconductor substrate 1, the waveguide core layer and the waveguide clad layer connecting the high-mesa structures of the plurality of semiconductor devices; and
a step of processing the waveguide core layer and the waveguide clad layer to form a waveguide including a multiplexer connected to each of the high-mesa structures of the plurality of semiconductor devices.

9. The method for manufacturing a semiconductor apparatus according to claim 6, further comprising:
a step of laminating a waveguide core layer and a waveguide clad layer on the semiconductor substrate 1, the waveguide core layer and the waveguide clad layer connecting the high-mesa structures of the plurality of semiconductor devices; and
a step of processing the waveguide core layer and the waveguide clad layer to form a waveguide including a multiplexer connected to each of the high-mesa structures of the plurality of semiconductor devices.

10. The method for manufacturing a semiconductor apparatus according to claim 2, wherein the high-mesa structures include a high-mesa structure for a modulator or an optical amplifier, and a high-mesa structure for a laser, and the high-mesa structure for the modulator or optical amplifier, and the high-mesa structure for the laser are linearly connected by a waveguide.
